(19) United States
(12) Patent Application Publication
(10) Pub. No.: US 2016/0330877 A1
(43) Pub. Date: Nov. 10, 2016

(54) MULTI-FOLDABLE, FLEXIBLE POCKET WIRELESS DISPLAY

(71) Applicant: Rupak Das, Arcadia, CA (US)

(72) Inventor: Rupak Das, Arcadia, CA (US)

(21) Appl. No.: 15/211,262

(22) Filed: Jul. 15, 2016

Related U.S. Application Data
(63) Continuation-in-part of application No. 14/986,606, filed on Dec. 31, 2015.
(60) Provisional application No. 62/101,990, filed on Jan. 10, 2015.
(60) Provisional application No. 61/975,898, filed on Apr. 6, 2014.

(51) Int. Cl. H05K 7/20; H01L 51/56; H01L 27/32; H01L 51/52

(52) U.S. Cl. CPC H05K 7/20954; H01L 51/529; H01L 51/56; H01L 27/3225; H01L 2251/5338; H01L 27/3227; H01G 11/08

(57) ABSTRACT

A foldable electronic display and method of its formation that can be unfolded and used as a monitor. The display comprises a plurality of layers, each formed with an allotrope of carbon and clubbed together to form a composite display sheet. The top most layer is a composite containing an allotrope of carbon such as graphene to provide a high optical resolution. Other layers act as a display screen, a circuit carrier, a layer to dissipate heat, and a final layer that has insulator properties.

### CROSS-REFERENCE TO RELATED APPLICATIONS

This application in a continuation-in-part of Nonprovisional patent application Ser. No. 14/986,606 which claims the benefit of Provisional Patent Applications Nos. 62/101,990, filed Jan. 10, 2015 and No. 61/975,898, filed Apr. 6, 2014.

### FIELD OF THE INVENTION

The present invention relates to a light-weight, multi-foldable, flexible, ultra-portable wireless display device made of multi-layered structure, from functionally active graphene network, which are in particular totally foldable, stretchable, retractable and instantly available to the common people for showing/expressing their ideas, speeches, presentations or impromptu workshops with uninterrupted power supply anytime, anywhere.

### BACKGROUND OF THE INVENTION

From time immemorial, educators, professors, lecturers, industrialists, speakers, businessmen and common people have been looking for a media display which is easy-to-use and can reach the mass quickly for instant display, teaching or disbursing information/knowledge to the onlookers. It would be even better if it can be made light-weight and placed in a shirt pocket for ease of carrying after folding like a hundred dollar bill. The ‘sought-after-of-the-hour’ is the complete solution produced by this invention. The uniqueness of this invention is the unconventionally-true complete and multiple-foldability like a hundred dollar bill, ultra-portability and flexibility of a graphene-based electronic display which can be used anytime, anywhere as an ultrathin monitor. The monitor/display will be governed fully with a remote-controlled device for super convenience and can be hooked up with any electronic text/media sources starting from Computer Applications, Video Games, Cable Television, Laptop Computer, Apple TV, Nintendo DX, and X-Box to simple Flash/Pen drive for crisp, effortless impromptu entertainment, shows or business speeches. The ultrathin monitor/display can be folded multiple times to fit in a shirt pockets and used whenever, wherever needed. The display doesn't need any external power source like normal corded/wireless displays. This device can be used specifically in the middle of a banished/forbidden land for Army and Soldiers for convenience and confirms the need of a laptop to be carried to the place-of-speech, totally redundant. Ultra-portability, wireless charging, feather-light weight yet stunningly sturdy configuration made the display reliable and extremely durable. The invention brings revolution to the hands of common people: instant access to communications and information sharing via wireless smart display.

The following discussion is with reference to the Publications listed under the References section hereof.

The self-adhesive property of graphene layers have been known lately for the attractive forces they have due to Van-Der-Waals forces and thus multiple layers can be attached without any external adhesive paste on top of one another. [1] and [2] dealt with the necessary adhesion theory in great depth and the construction of multiple stacked layering will be done following their efforts in this invention. The inventors went great depth regarding the adhesive properties are concerned but didn't mention the continuity towards bendability or multiple foldability of the graphene based substrates. The present invention will work on furthering their technology and theory towards multiple foldability similar to folding a newspaper being normally available in the market.

European patent, EP2637862 A1, world patents WO2013105768 A1, WO2011016832 A2, WO2014030954, WO2014038898, US patents US0055429 A1, US0042390 A1, US0065402 A1, US0030600 A1, and European patent EP2706435 A2 explained on their theories of making simple flat screen displays with graphene as the back bones. One step forward has been done with the help of flexible polymeric bonds and graphene sheets made with the theory of transparency in mind. U.S. Pat. No. 8,591,680 B2, US0061612 A1, US0049463 A1, US0055429 A1, US0043263, US0049464 A1, US0055429 A1, US0034926 A1, world patents WO2014030954 A2, WO2013051761 A1, Chinese patents CN103151101 A, CN103279239 A, and European patents EP2327662 A1 and EP2439779 A2 have worked along the same line in making the transparent graphene display flexible. [9] and [8] have demonstrated the theory behind making Ultraflat display with graphene mono-layers or sheets. The work towards making the transparent displays bendable, multiple-foldable and stretchable at the same time is going to be the next step forward in the present invention.

One step forward towards making a better high-resolution organic display was being done by world patents WO2014030957 A1, WO2014035148 A1, WO2014038898 A1 and WO2014021658 A1. The screen resolution and the environment-friendly technology are of prime importance for the next generation. Resolution on screen will be elevated by a higher degree than the best in the industry with the technology similar to being used in [6]. The next futuristic work towards making the displays with highest resolution on a substrate that is bendable, multiple-foldable and stretchable at the same time is going to be the next step forward in the present invention.

The US patents worked on printing the electronic circuits on graphene sheets encompass U.S. Pat. No. 8,650,749 B2, US0082984 A1, US0027161 A1, US0086631 A1, US0237679 A1 and Chinese patent CN203083964 U specially. Electronic circuits can be printed/embedded on the graphene sheets by similar theory adopted by [4], [5], [17], [18], [19] or [20]. The printed circuits based on specific graphene depositions, having properties like multiple-foldability are going to be the next challenge undertaken in the present invention.

Smart panel displays inherit the inclusions of non-volatile memories and some of the patents mentioned here involved the technology. U.S. Pat. Nos. 8,519,450 B1 and 8,557,686 B1 are among them. The futuristic application of the similar theory along with bendable, multiple-foldable and stretchable substrate is going to be the next step forward in the present invention.

Heat dissipation and thermal management has become a critical issue in the thin graphene displays and have been markedly addressed in the world patent WO2013149446 A1 and the US patents US0329366 A1, US0085713 A1, US0128439 A1 and US0264041 A1. Multiple-foldable and stretchable substrate is going to be added to the already existing technology on graphene thermal management.

The technology behind putting a thin sheet of graphene with the power storage built or printed on has been made reality with the ideas in world patents WO2014033282 A1, WO2014020915 A1, WO2014028978 A1, Chinese patents CN103413951 A, CN103490478 A, CN103432994 A, CN103413950 A, CN103428972 A and US patents

US0053973 A1, US0022533 A1, US0026155 A1, US0011673 A1, US0061060 A1, US0049879 A1, US0030181 A1. The power storage can be built with the thin layers of fuel cells or ultra-capacitors. Solar cells can also be printed for power generation as per the European patent EP2439779 A2. The next step along the same research will be the addition of bendable, multiple-foldable and stretchable substrate in the present invention.

In order not to short circuit or throw electrical shocks to users, the last layer may be made as an insulator and US patents US0313512 A1, US0048774 A1, US0000805 A1, US0030600 A1 and US0065402 A1 addressed the theory behind that. The last layer preferably would be constructed with the theory adopted by [3] as the graphene bilayer.

Bi-Layer graphene will be used on the similar theory along with bendable, multiple-foldable and stretchable substrate in the present invention.

The doped PDMS and its similar manufacturing detailed procedure can be seen in

. The doping has been done with carbon nano tubes (CNT) in the literature [14] but the present invention would replace the doping materials with the novel graphene nano structures, thus extending the possibility several times for great user-friendly properties. Crack self-healing materials' will be used as in [15] with the possibility of replacing the materials' with their derivatives for better properties.

Virtual springs' impartment inside the substrates is detailed in [12] and [13]. Similar procedure will be followed with different materials' (Graphene, doped graphene or its derivatives) being used in the literature for better chemical/physical properties.

Latest OLED manufacturing is defined in US0086631 A1 and 0237679 A1 as the basic frame work. Similar detailed procedure will be used for the OLED manufacturing for flexible and foldable composite structure and encapsulations with different materials' mentioned in this invention (Graphene, doped graphene or its derivatives).

Ultrafast communications via the technology and graphene infrastructure will be mimicked by the theory similar to usage in [7] with different materials' used in literature (Graphene, doped graphene with different substrates mentioned in literature).

Wireless charging theory will be followed similar to being used in [10] with different materials' used in literature (Graphene, doped graphene with different substrates mentioned in literature).

Transparent electrodes will be used in the whole system similar to being adopted in [11] with different materials' used in literature (Graphene, doped graphene with different substrates mentioned in literature).

Provisional Patent Application 61/975,898 proposed a novel display bendable and fully foldable. The other additional features of the invention were powerless display, wireless charging etc. This present invention continued the trend as base and put in cushioning nano bubbles, virtual graphene springs, extra-flexible substrates and healing materials for further claims.

### BRIEF SUMMARY OF THE INVENTION

The invention comprises a foldable electronic display that can be unfolded and used as a monitor comprising a plurality of layers formed of a material selected from an allotrope of carbon such as graphene, carbon nano-tubes and carbon nano-fibers and clubbed together to form a composite display thin sheet. The top most layer is a composite containing an allotrope of carbon such as graphene to provide a high optical resolution. Other layers act as a display screen, a circuit carrier, a layer to dissipate heat, and a final layer that has insulator properties.

One embodiment of this invention is the complete perfect foldability, ultra-portability and super flexibility of the graphene-based electronic display that can be unfolded and used anywhere, anytime as an ultrathin feather-weight monitor whenever needed. Graphene is an allotrope of carbon in the form of a two-dimensional, atomic-scale, honey-comb lattice in which one atom forms each vertex. It is the basic structural element of other allotropes, including graphite, charcoal, carbon nanotubes and fullerenes.

The second embodiment may be expressed as the substrate that is being used in the whole display. The organic-based materials' (i.e. PDMS, doped-PDMS or similar) are used as substrates which have properties that let the composite layers bent from 0° to 4° unparallel ‘angle-of-bending’ altogether.

The third embodiment is the use of virtual springs made of graphene materials/depositions that stretches and compresses according to the need of foldability.

The fourth embodiment is the use of nano-bubbles made of inert gases that cushions the stresses created during folding and unfolding of the system.

The fifth embodiment is the inclusion of functionally graded substrates (according to their physical and chemical properties) in all the external layers except the first two, created for actual display.

The sixth embodiment is the use of self-healing materials used inside the base substrate in all the layers for regaining original shape when the stress/strain is released.

A totally multi-foldable, flexible, pocket wireless display will make a groundbreaking era in the world of communications, information technology, Corporate/Business Sector and media realms as there's always a need for super-light-weight, ultra-portable, wireless, fully-foldable display. The ultra-foldable, totally-bendable, feather-light-weight, super-fast monitor/display can be placed in a shirt pocket with the virtue of ultra-portability as a result of the present invention. The display essentially consists of about 7 functional layers (may be less depending on the available technology), clubbed together to form a composite display thin sheet. Wireless charging, automatic remote energy storage, in-built non-volatile memory along with the convenience of portability makes it a “device-of-the-need” at anytime, anywhere, irrespective of availability of outlet power sources. The prime ingredient of the cutting-edge sophistication is the hexagonal shaped structure of one-atom thick Graphene network. The availability, affordability, exceptional physical properties of the Functional layers of the Compound Display put together in a simple nut-shell would be available to the common people at a very affordable rate in the near foreseeable future

The foregoing summary, as well as the following detailed description, is better understood when read in conjunction with the associated drawings. For the purpose of illustrating the subject matter, several drawings examples are given that illustrate various embodiments; however, the invention is not limited to the specific systems and methods disclosed. Typically, the monitor/display will be controlled with a remote-controller for user-convenience and can be hooked up with any electronic text/media sources starting from Computer Applications, Video Games, Cable Television, Laptop Computer, Apple TV, Nintendo DX, and X-Box to simple Flash/Pen drive for impromptu entertainment, shows or business speeches. The ultrathin monitor/display can be totally folded multiple times as in a folded hundred dollar bill to fit in a shirt pocket for use, whenever, wherever needed multiple times. The display doesn't need any external direct power sources and makes the need of a laptop to be carried to the place-of-speech redundant. Ultra-portability, wireless charging, light weight yet ultimate-sturdy structural integrity made the display super reliable and extremely durable. The invention brings revolution to the instant communication, portability, convenience, telecast and world of information.

### BRIEF DESCRIPTION OF THE DRAWINGS

All the features, aspects, and advantages of the present subject matter will become better understood when the following detailed description is read with reference to the accompanying drawings, wherein:

FIG. 1 is a non-limiting functional Layer 1 of the system especially made for the protection of the display screen.

FIG. 2 is another non-limiting functional Layer 2 of the same system made as the actual display layer.

FIG. 3 is another non-limiting functional Layer 3 of the same system made for printed electronic circuits made of graphene.

FIG. 4 is another non-limiting functional Layer 4 of the same system made for imprinting non-volatile memory.

FIG. 5 is another non-limiting functional Layer 5 of the same system made as the power source and storage.

FIG. 6 is another non-limiting functional Layer 6 of the same system made for heat dissipation and thermal management.

FIG. 7 is another non-limiting functional Layer 7 of the same system used as an insulator.

FIG. 8: All the layers 901, 902, 903, 904, 905, 906, 907 are added one after another in a polymeric composite, with the sensor window 909.

FIG. 9: Back view of the composite layers 901, 902, 903, 904, 905, 906 and 907.

FIG. 10: Layer 1 901 from the front view with the sensor window 909.

FIG. 11: Remote controller 925 with the display tabs 926 and first media slot 924

FIG. 12: Remote controller 925 with the display 901, sensor window 909 and USB drive in first media slot 924

FIG. 13: Remote controller 925 with the display 901, sensor window 909 and wireless laptop 929 connector 928 in second media slot

FIG. 14: Remote controller 925 with the display 901, sensor window 909 and wireless cable stream connector 930 in third media slot

FIG. 15: Remote controller 925 with the display 901, sensor window 909 and dish connector 931 in fourth media slot

FIG. 16: Remote controller 925 with the display 901, sensor window 909 and satellite stream connector 932 in fifth media slot

FIG. 17: Functionally Structured Substrates (FSS) of all the layers (Side view)

FIG. 18: Functionally Structured Substrate (FSS) with Virtual Springs (Side view)

FIG. 19: Functionally Structured Substrate (FSS) with Nano-Bubbles (Side view)

FIG. 20: Functionally Structured Substrate (FSS) with Virtual Springs and Nano-Bubbles (Side view)

FIG. 21: Functionally Structured Substrate (FSS) with Virtual Springs and Nano-Bubbles (Top View)

### DETAILED DESCRIPTION OF THE INVENTION

In an embodiment, the substrates may be made of organic materials, which may be amide, imide, carbon derivatives, aromatic special polymers, electro-luminescent polymers, tetrapod quantum dots for excellent reproduction of graphics. Organic polymers like poly (p-phenylene-vinylene), organometallic chelates, conjugated dendrimers, triphenylamine and derivatives, fluorescent dyes, perylene, rubrene and quinacridone derivatives and phosphorescent dyes may be used in the manufacturing of the thin individual substrates layers.

PEN, Polyimide, ABS, Acrylic, Kydex, Noryl, Polycarbonate, Polystyrene (HIPS), Polysulfone, PVC, Radel R, Ultem, Acetal, HDPE, LDPE, Nylon, PBT, PEEK, Polypropylene, PPS, PTFE, PVDF (Kynar), UHMW-PE, PAI (polyamide-imide), Vespel, Polyimide Shapes, PDMS, Doped PDMS, Neoprene, zytel, crastin, hytrel and zylon may be used individually or as a mixture of more-than-one compounds/chemicals for suiting our purpose of super-flexibility and foldability. Doping may be used to multiple components to achieve extra-ordinary user-friendly properties of the system.

The specially manufactured substrates will have such properties so that it can be bent as a thin composite layer up to 0° to 4° bending radius unparallel to any invention related to bendable displays so far. The display can be folded multiple times like a 100 dollar bill and put in side/front pockets. Whenever they are needed, they can be unfolded and hung on the wall or any hanger to start the operational display.

In an embodiment, nano-bubbles of inert gases will be introduced in the substrates so that the bubbles take the stress and strain shocks during folding and unfolding for additional flexibility. The inert gases may be any noble gas like crypton, xenon, argon, neon, radon or even nitrogen or similar non-reactive gaseous species. The nano-bubbles will act as small flexible balloons that act as shock absorbers.

In an embodiment, functionally (i.e. chemical and physical compositions) structured substrates may be used depending on the position of the layers from the front of the display. The extreme-most layer from the front will be having the most flexibility with the front layer the least, comparatively. Thus during folding and unfolding, the substrate will recuperate to its original forms very easily with almost no residual stresses. The novelty of this invention is the unconventional complete multiple foldability, ultra-portability, flexibility and immensely-fast response time of a graphene-based electronic display which can be used anywhere as an ultrathin monitor, even without any available power sources. The monitor/display will be governed fully with a remote-controlled device for convenience and can be hooked up with any electronic video/text/media /streaming starting from Computer Applications, Video Games, Cable Television, Laptop Computer, Apple TV, Nintendo DX, and X-Box to simple Flash/Pen drive for crisp, effortless impromptu entertainment, shows or business speeches. The ultrathin monitor/display can be folded multiple times to fit in a shirt pocket for use whenever, wherever needed, which hasn't yet been done so far in the electronic display world. The display doesn't need any power source for its operation if it's not available at the point of operation.

In the embodiment of the present disclosure, the basic structure of each layer explained here is a sandwiched design of graphene or similar carbon structures like carbon nano-tubes, carbon nano-fibers etc., substrates and other components. Aromatic polymers, electro-luminescent polymers and tetrapod quantum dots may be used for excellent reproduction of graphics. Organic polymers like poly (p-phenylene-vinylene), organometallic chelates, conjugated dendrimers, triphenylamine and derivatives, fluorescent dyes, perylene, rubrene and quinacridone derivatives and phosphorescent dyes are to be used in the manufacturing of the thin individual layers. PEN, Polyimide, ABS, Acrylic, Kydex, Noryl, Polycarbonate, Polystyrene (HIPS), Polysulfone, PVC, Radel R, Ultem, Acetal, HDPE, LDPE, Nylon, PBT, PEEK, Polypropylene, PPS, PTFE, PVDF (Kynar), UHMW-PE, PAI (polyamide-imide), Vespel, Polyimide Shapes, PDMS, doped PDMS, Neoprene, zytel, crastin, hytrel and zylon may be used also individually or as a mixture of more-than-one compounds/chemicals to suit our purpose of super-flexibility. Doping may be used to multiple components to achieve extra-ordinary properties of the system. Organic Light Emitting Display (OLED) technology will be used to get the best output on the screen. OLED technology deals with organic layers sandwiched between anode (emitter) and cathode (conductor) layers as described above. The layers can be made by different methods like spin coating, organic vapor phase deposition, fine metal mask process, red-green-blue (RGB) pixel patterning, laser-induced patterning, solution printing process, organic vapor jet printing (OVJP), photolithography, thermal evaporation, methods described in [0086631 A1/0237679 A1] or deposition of a Langmuir-Blodgett film etc. We may use the anode as ruthenium/carbon complex etc. and cathode as gallium-indium alloy/carbon etc. polyethylene terephthalate (PET) may not be used for its limited flexibility. The depositions are to be made on thin substrates. The whole system will have very low energy consumption, immediate response time, minimum visual angle and high quality picture onscreen. All the electrical circuits can be printed on the composite layers by low-cost inkjet printing technology also. The typical response time will be way less than the best in market 0.01 ms, enabling a refresh rate more than 100,000 Hz available today. In the embodiment, the anode may be made of series of elements similar to ruthenium/carbon and other transition metals in the periodic table. Similarly, the cathode may be made of similar elements like gallium, indium etc. in the periodic table from V groups or carbon derivatives. The display will be wirelessly charged via the remote control source, directly or indirectly.

The number of total functional layers may be 7, or more or less depending on the advancement of manufacturing technology and the need-of-the-hour. Multiple functionalities may be incorporated in a single layer reducing the total number of functional layers and weight accordingly. The size of the display may span from 1 inch by 1 inch to several inch by several inch depending on the need of the consumer. The display itself may be easily made by combining small pieces of several displays together with the technology similar to adhesive fusion, which hasn't been done so far.

The prime ingredient or component of this novel invention is “Graphene”, a carbon structure by nature.

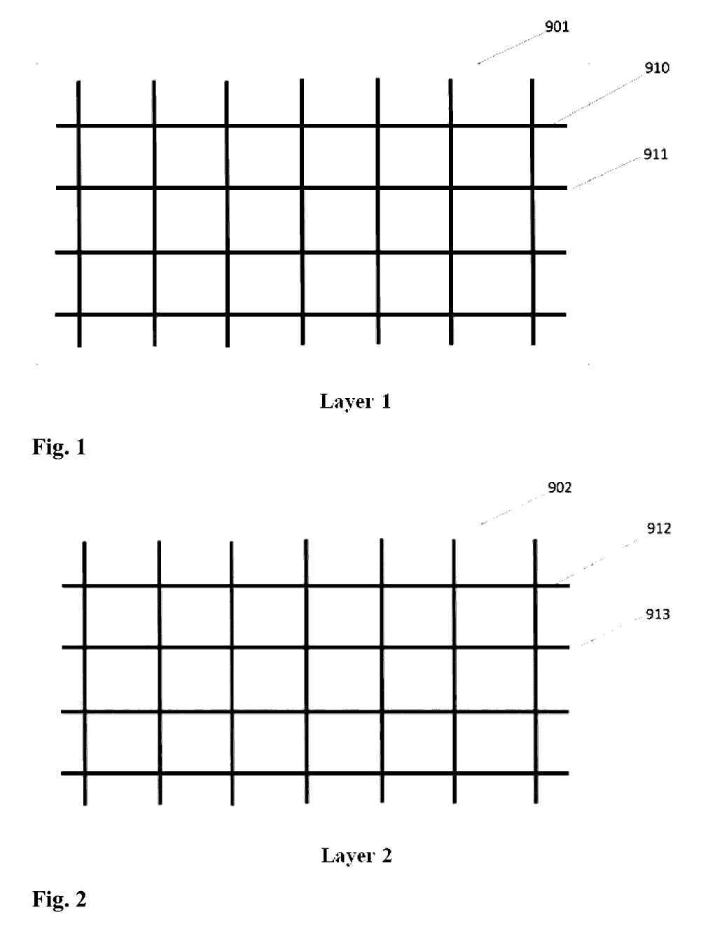

Referring to FIG. 1, the top most layer 901 is going to be transparent, conductive and highly optical-intensive in order to provide unparallel optical resolution. It's going to be a composite of graphene 910 and a mixture of polymers/chemicals/elastomers 911 having comfortable mixing, coefficient of expansion, tensile and other physical properties. Vander Waals' forces acts great on the graphene surface to adhere to elastomers. This layer will act as a shield for the whole system. Interface adhesion energy of monolayer and multilayer graphene on substrates are based on the bond relaxation consideration. Membrane thickness and interface confinement condition determine the adhesion energy here. It was found that the membrane thickness and the interface confinement condition determine the adhesion energy. The relationship between the critical interface separation and the graphene thickness showed that the interface separation in the self-equilibrium state drops with decreasing membrane thickness. The size-dependent Young's modulus of graphene membrane and the interfacial condition were responsible for the novel interface adhesion energy. Adhesion energy describes how “sticky” two things are when placed together. Scotch tape is one example of a material with high adhesion; the gecko lizard, which seemingly defies gravity by scaling up vertical walls using adhesion between its feet and the wall, is another. The first direct experimental measurements of the adhesion of graphene nanostructure, showed that so-called “Van Der Waals forces”—the sum of the attractive or repulsive forces between molecules—clamp the graphene samples to the substrates and also hold together the individual graphene sheets in multilayer samples. The researchers found the adhesion energies between graphene and the glass substrate were several orders of magnitude larger than adhesion energies in typical micro-mechanical structures, an interaction they described as more liquid-like than solid-like. We need to see what's best for the adhesion needs for the system. Thermal management will be introduced if there's a need for the calendaring or lamination techniques.

Referring to FIG. 2, this layer 902 will be of similar composition of a polymer/chemical/elastomer 913 and graphene 912 but will be acting primarily as the display screen. This layer will have the small communication window for direct data transfer with the remote control device. This communication window will be attached to Layer 1 also and can be seen from the front side of the display. The prime importance of the layer will be to transmit the data properly on screen with unparallel resolution.

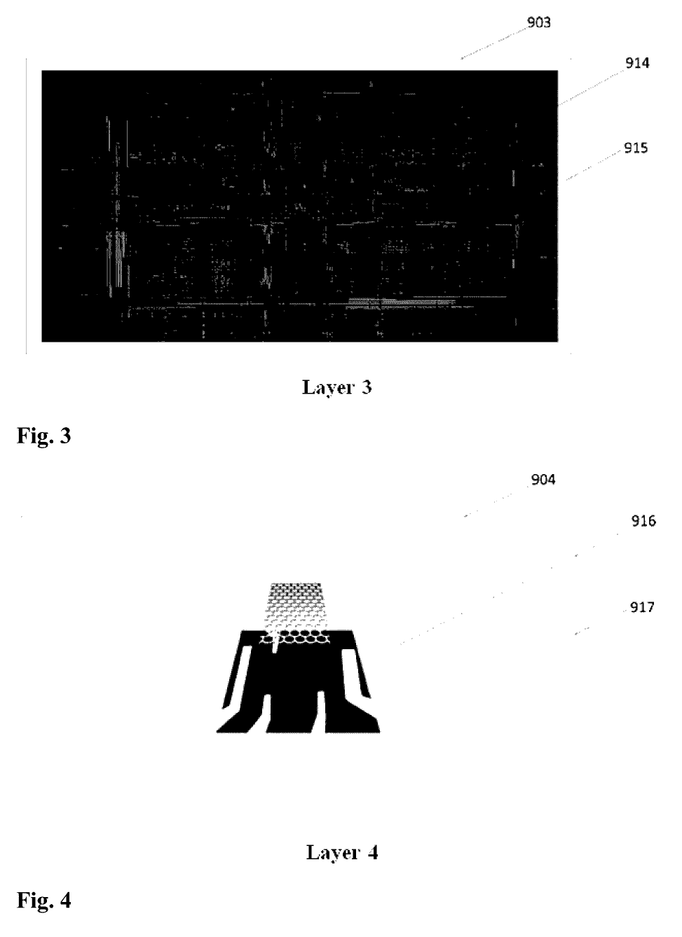

Referring to FIG. 3, this layer 903 will essentially have the heart of the device and all the electrical circuitry 914 will be printed on this composite 915 sheet. All the layers will be connected to this layer for proper power distribution and functioning. The detailed manufacturing of the graphene based printed circuits may be found in [17], [18], [19] and [20]. In the figure, a printed circuit board may be configured to include a substrate, elastic electrodes and a seed layer. In order to assist in understanding the present invention, a plan view of the printed circuit board according to the preferred embodiment of the present invention is shown in FIG. 3. For example, in the case in which the substrate is the flexible substrate, the substrate may be formed of a polymer film, such as a polyimide (PI) or PDMS/doped-PDMS composition like elaborated above in the materials' explanation. The elastic electrode may be formed on the substrates. The elastic electrodes may be made of graphene or graphene oxide. The graphene may be made of carbon atoms and be a thin layer having a thickness of one carbon atom. The graphene may have electric conductivity about 100 times or higher than that of copper. In addition, the graphene may be a substance capable of moving an electron at a speed about 100 times or faster than that of single crystal silicon mainly used in a semiconductor. In addition, the graphene may have strength 200 times or more than that of steel and have thermal conductivity two times or more than that of diamond. In addition, the graphene may be a substance that has excellent elasticity to maintain an electric property thereof even in the case of being strained or bent. The nonmetal electrode may be formed on the elastic electrodes. For example, the nonmetal electrodes may be formed on both sides of the elastic electrode. The nonmetal electrodes may be formed on a region in which occurrence of deformation of the substrate is less. In the case in which the substrate is bent, the largest deformation is generated at a central region of the substrate and less deformation is generated at regions of both sides thereof as compared to the central region. Therefore, the electrodes may be formed on both sides of the elastic electrode formed on the substrate. The seed layer may be formed between the elastic electrode and the nonmetal electrode. The seed layer may serve as a lead line when the elastic electrode is formed. The seed layer may be made of a conductive material. For example, the seed layer may be made of the same conductive nonmetal as that of the nonmetal electrode. Although the preferred embodiment of the present invention shows the case in which the printed circuit board includes the seed layer, the present invention is not limited thereto. That is, the nonmetal electrode serves as the lead line for forming the elastic electrode, such that the seed layer may be omitted. According to the preferred embodiment of the present invention, the nonmetal electrodes may be formed on both sides of the substrate so as to be spaced apart from each other. The nonmetal electrodes formed so as to be spaced apart from each other as described above may be electrically connected to each other by the elastic electrode. Since the elastic electrode is made of the graphene to have excellent elasticity, even though deformation is generated in the substrate, the possibility that a defect such as electrode disconnection, or the like will be generated is low. That is, according to the preferred embodiment of the present invention, the nonmetal electrodes are formed on both sides of the substrate in which the deformation is hardly generated and are connected to each other by the elastic electrode having the high elasticity, thereby making it possible to improve durability and reliability of the printed circuit board. FIGS. 1 to 7 are views showing similar methods for manufacturing each layer of the system according to a preferred embodiment of the present invention. In order to assist in understanding the method for manufacturing the individual layers, according to the preferred embodiment of the present invention, a plan view of the layers are shown in FIG. 10.

Referring again to FIG. 2, a carrier member having a nonmetal layer formed thereon may be provided. Here, the nonmetal layer may be formed over the entire upper surface of the carrier member. According to the preferred embodiment of the present invention, the carrier member may have a form such as a nonmetal foil/sheet, a polymer, or the like. The nonmetal layer may be later patterned to become an electrode. The nonmetal layer may be made of a conductive material.

Referring again to FIG. 3, the nonmetal layer may be primarily patterned. The primary patterning may be per formed so that the nonmetal layer remains only on a portion on which the electrode is to be formed. That is, remaining regions of the nonmetal layer except for the region on which the nonmetal electrode is to be formed may be etched. Here, the primary patterning may be performed using any one of general etching methods such as wet etching, dry etching such as reactive ion etching (RIE), and the like.

Referring to FIG. 4, this layer 904 will have the non-volatile memory 916 embedded as a microprocessor chip or distributed functional layer on the composite 917 for super-fast reproduction of the transmitted data almost having zero lag. An elastic nonmetal layer may be formed. The elastic nonmetal layer may be formed on the primarily patterned nonmetal layer and the carrier member exposed by the patterning of the nonmetal layer. The elastic nonmetal layer 917 may be made of graphene or graphene oxide. The graphene may be made of carbon atoms having a thickness of one carbon atom. The graphene may have electric conductivity of about 100 times higher than that of copper. In addition, the graphene may be a substance capable of moving an electron at a speed about 100 times faster than that of a single crystal silicon mainly used in a semiconductor. In addition, the graphene may have strength 200 times more than that of steel and have thermal conductivity two times or more than that of diamond. In addition, the graphene may be a substance that has excellent elasticity to maintain electric property thereof even in the case of being strained or bent the elastic nonmetal layer 917 may be formed using a reduction method. In addition, an elastic electrode may be formed using a well-known non-selective forming method as well as the reduction method to make non-volatile memory circuits. The process is very similar to making the electronic printed circuits depicted above.

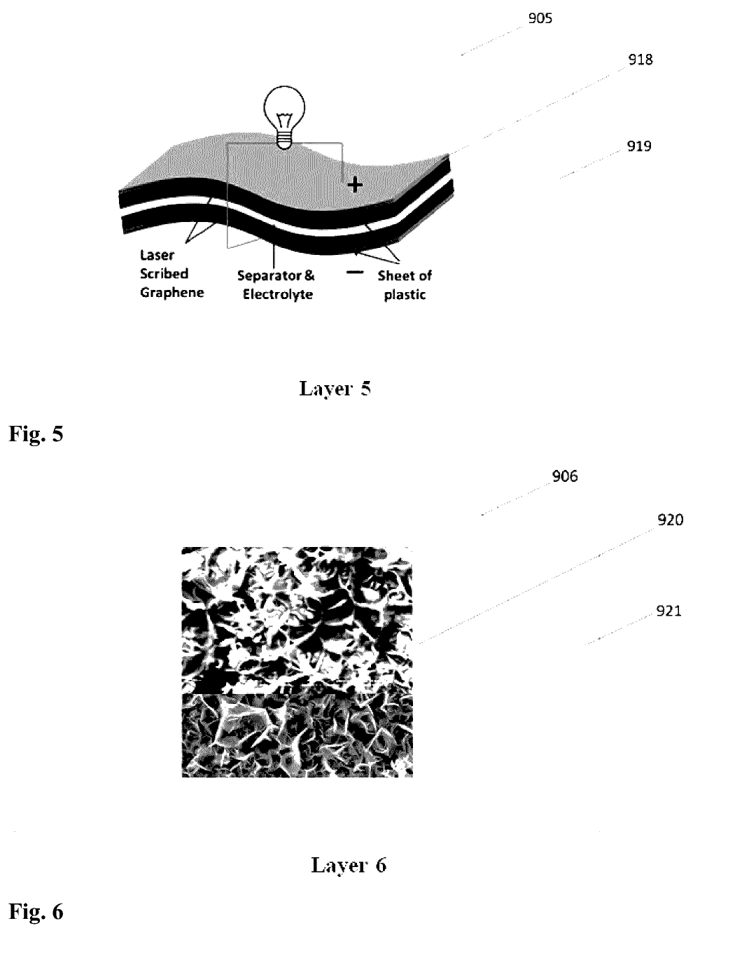

Referring to FIG. 5, this layer 905 will have the capability of storing energy in super/ultra-capacitors 918 on the composite 919. The solar cell embedded here will non-stop gather energy from the sunlight and radiated photons from atmosphere and store it in the super-capacitor for future usage. The solar cell will work 24/7 and produce electricity for storage and instant usage. The capacitor will be used for instant energy supply to the system and storing the produced electricity from the solar cell. The solar cell may be added with a miniature fuel cell as back-up if needed. The portable cartridge for the fuel cells can be supplied later. Thus the energy conversion takes a leap and the device gets unperturbed flow of energy whenever, wherever needed. Moreover, the layer will have the capability to accept electrical charges or electrical streams wirelessly via electrical dissipaters or power sources. Referring again to FIG. 5, a substrate may be formed on the elastic nonmetal layer. The substrate may be at least one of a flexible substrate, a rigid substrate, and a rigid and flexible substrate. For example, in the case in which the substrate is the flexible substrate, the substrate may be formed of a polymer or the like explained above. The substrate may be formed on the elastic electrode by a method such as a spray coating method, multiple selective printing, screen printing, a lamination method, or the like. The different layers of the fuel cells or solar cells may be printed in the way very similar to described above for layer 3.

Referring to FIG. 6, this layer 906 will essentially work as the thermal dissipater 920 in composite 921 and keep the device cool after hours of continuous operations. The elastic nonmetal layer may be patterned so as to remain only on the primarily patterned nonmetal layer suitable for heat dissipation or thermal management. That is, the elastic nonmetal layer may be patterned in a form of the elastic electrode. The layer 6 may be made very similar to that explained in making layer 3 above.

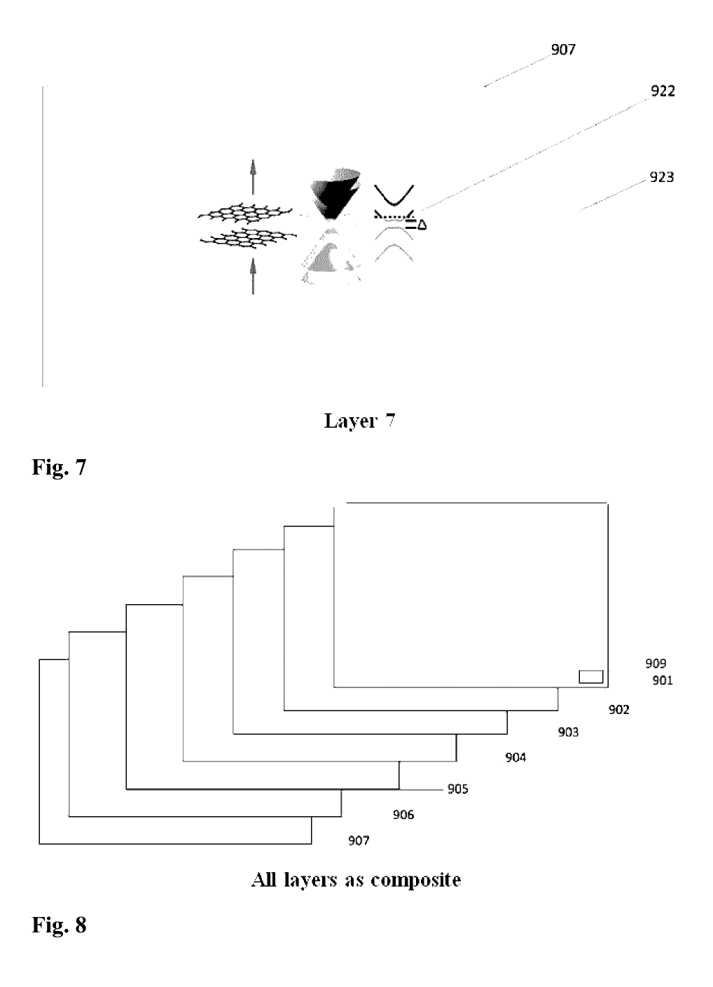

Referring to FIG. 7, the last layer 907 will be added as the insulator 922 in the composite 923 in order to prevent any accidental electrical shock, leakage or discharges. Bilayer graphene (BLG) will be used here whereas it works as an insulator. A property of “bilayer graphene” (BLG) that the researchers say is analogous to finding the Higgs boson in particle physics. Because of graphene's planar and chicken wire-like structure, sheets of it lend themselves well to stacking. BLG is formed when two graphene sheets are stacked in a special manner. Like graphene, BLG has high current-carrying capacity, also known as high electron conductivity. The high current carrying capacity results from the extremely high velocities that electrons can acquire in a graphene sheet. In investigating BLG's properties, scientists found that when the number of electrons on the BLG sheet is close to 0, the material becomes insulating (that is, it resists flow of electrical current)—a finding that has implications for the use of graphene as an electronic material in the semiconductor and electronics industries. BLG becomes insulating because its electrons spontaneously organize themselves when their number is small, instead of moving around randomly, the electrons move in an orderly fashion. This is called ‘spontaneous symmetry breaking’ in physics, and is a very important concept since it is the same principle that ‘endows’ mass for particles in high energy physics.” The physics which gives these particles their mass is closely analogous to the physics which makes the mass of a proton inside an atomic nucleus very much larger than the mass of the quarks from which it is formed. Single layer graphene (SLG) is gapless, however, and cannot be completely turned off because regardless of the number of electrons on SLG, it always remains metallic and a conductor. BLG, on the other hand, can in fact be turned off. What is tremendously exciting though is that this work suggests a promising route trilayer graphene and tetralayer graphene, which are likely to have much larger energy gaps that can be used for digital and infrared technologies. Referring again to FIG. 7, the elastic electrode 922 may be made of graphene or graphene oxide.

Referring to FIG. 8, all the layers 901, 902, 903, 904, 905, 906, 907 are added one after another in a polymeric composite, with the sensor window 909.

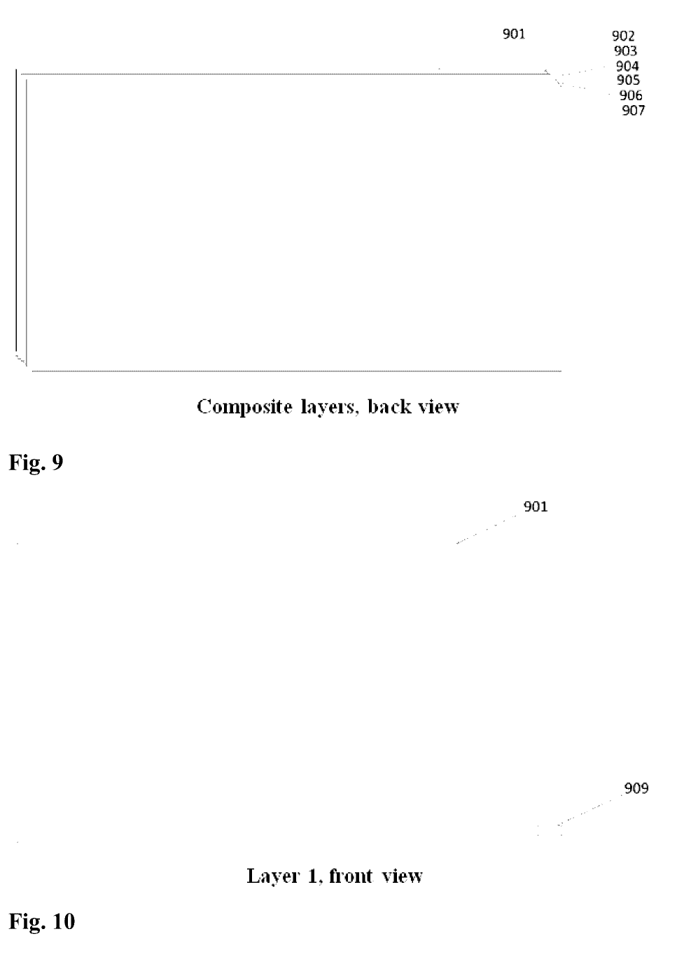

Referring to FIG. 9, a back view of the composite layers 901, 902, 903, 904, 905, 906 and 907 is shown.

Referring to FIG. 10, layer 1 901 from the front view with the sensor window 909 is shown.

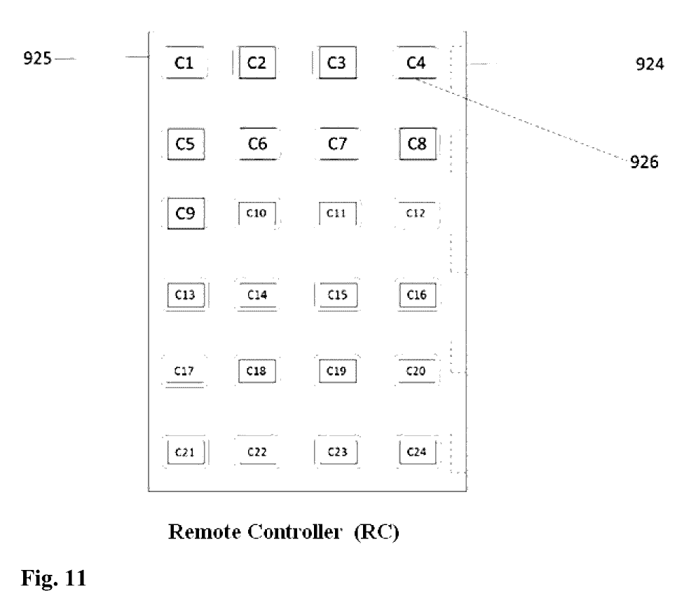

Referring to FIG. 11, remote controller 925 with the display tabs 926 and first media slot 924 is shown.

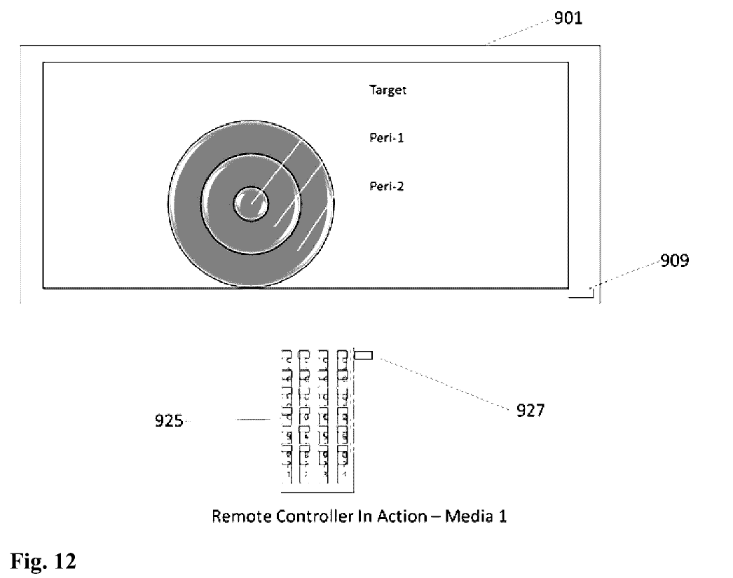

Referring to FIG. 12, remote controller 925 with the display 901, sensor window 909 and USB drive in first media slot 924

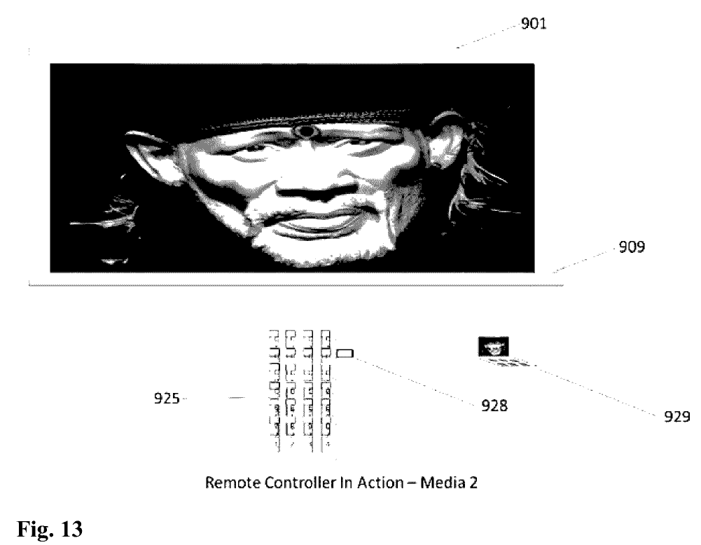

Referring to FIG. 13, Remote controller 925 with the display 901, sensor window 909 and wireless laptop 929 connector 928 in second media slot is shown.

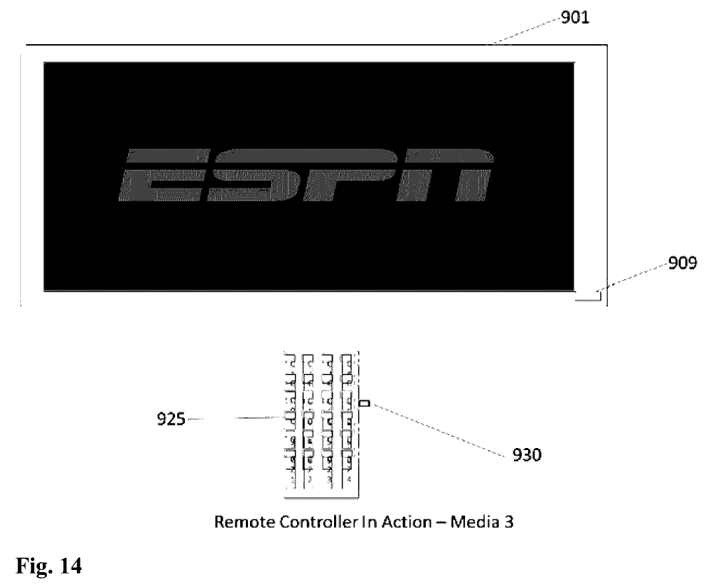

Referring to FIG. 14, remote controller 925 with the display 901, sensor window 909 and wireless cable stream connector 930 in third media slot is shown.

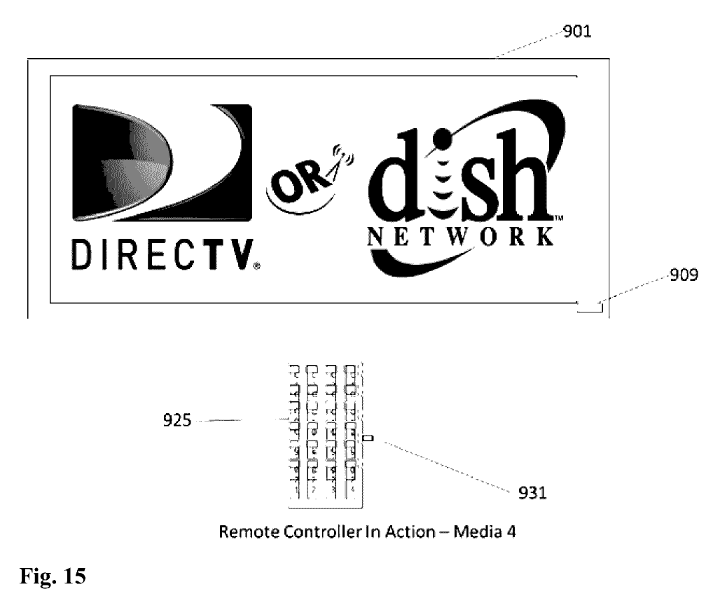

Referring to FIG. 15, remote controller 925 with the display 901, sensor window 909 and dish connector 931 in fourth media slot is shown.

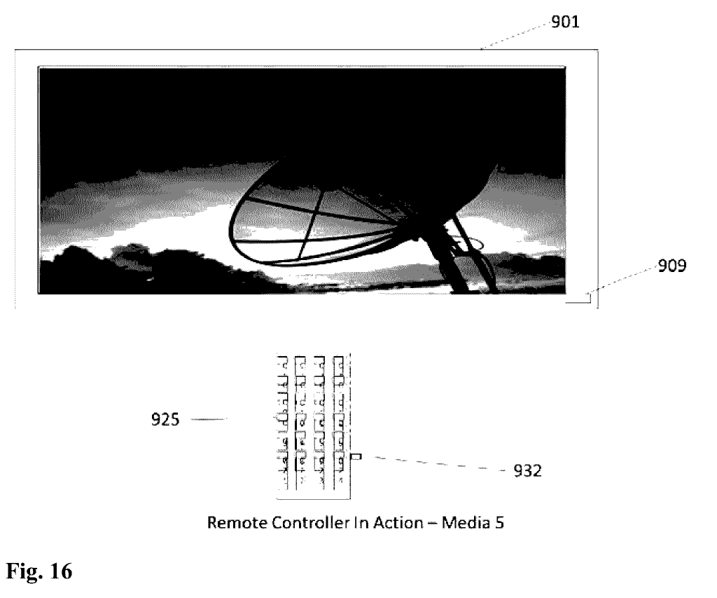

Referring to FIG. 16, remote controller 925 with the display 901, sensor window 909 and satellite stream connector 932 in fifth media slot is shown.

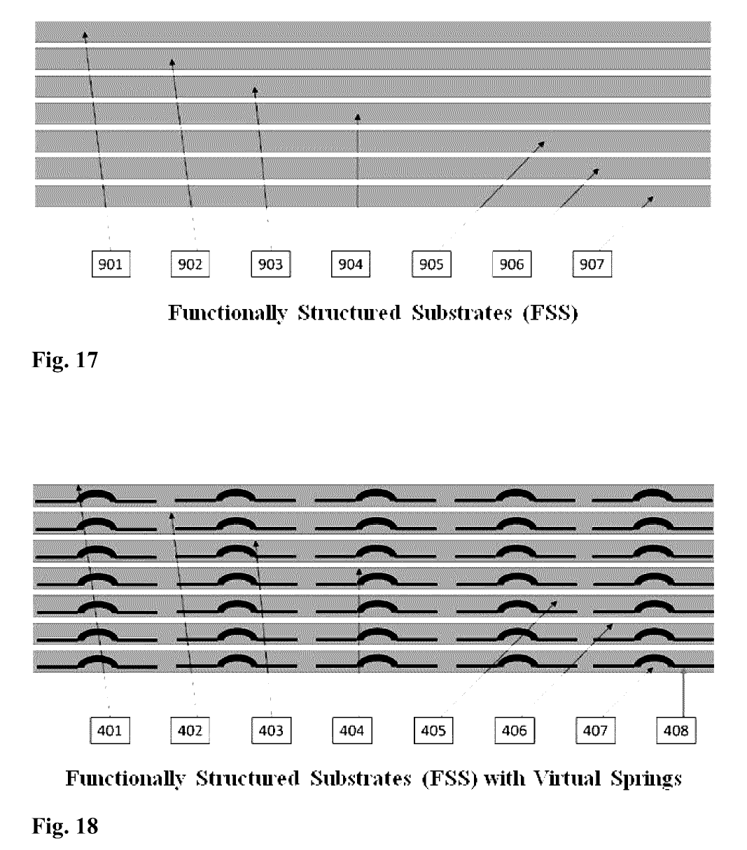

Referring to FIG. 17, a side view of the functionally Structured Substrates (FSS) of all the layers is shown.

Referring to FIG. 18, a side view of the functionally Structured Substrate (FSS) with Virtual Springs is shown.

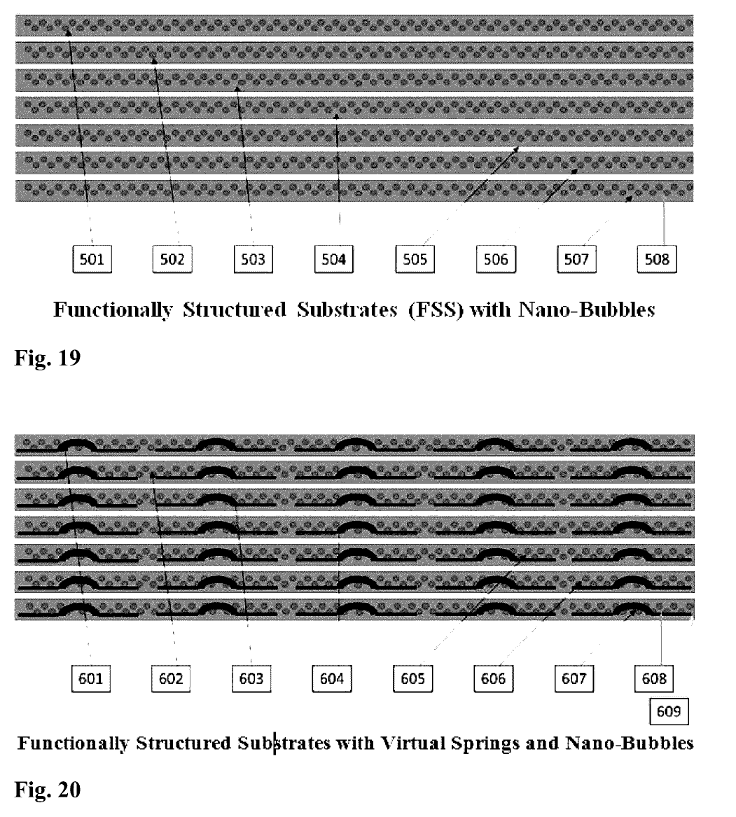

Referring to FIG. 19, a side view of the functionally Structured Substrate (FSS) with Nano-Bubbles is shown.

Referring to FIG. 20, a side view of the functionally Structured Substrate (FSS) with Virtual Springs and Nano-Bubbles is shown.

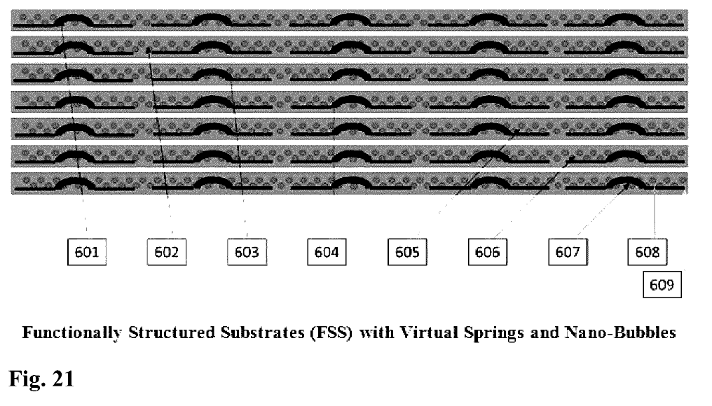

Referring to FIG. 21, a top view of the Functionally Structured Substrate (FSS) with Virtual Springs and Nano-Bubbles is shown.

The printed circuit layers and the method for manufacturing the same according to the preferred embodiments of the present invention, the transparent electrodes are formed on both sides of the substrate by the elastic electrodes made of the graphene, thereby making it possible to provide the printed circuit board having high durability against the deformation thereof.

With the printed circuit board and the method for manufacturing the same according to the preferred embodiments of the present invention, the elastic electrode has a very thin, thereby making it possible to implement a micro thin flexible printed circuit board.

This device can be used by Army, Soldiers in the middle of a banished land effortlessly and for flawless, continuous communications. The size of the display device can be made as big as needed and has no bounds. It can be hanged anywhere for instant communications and transfer of data, media or other modes of communications. All the features bundled so effortlessly in a simple ultrathin display couldn't be solved by the earlier inventors. This device makes the need of a laptop to be carried to the place-of-speech totally redundant. Ultra-portability, wireless charging, feather-light yet sturdy configuration made the display super sturdy, reliable, exceptionally user-friendly and durable. Other inventors couldn't assemble this height of convenience to the techno-savvy community ever before. The invention brings revolution to the instant communication and information savvy fast world. This written description uses examples to disclose the subject matter contained herein, including the best mode, and also to enable any person skilled in the art to practice the invention, including making and using any devices or systems and performing any incorporated methods. The patentable scope of the disclosure is defined by the claims, and may include other examples that occur to those skilled in the art. Such other examples are intended to be within the scope of the claims if they have compositional elements that do not differ from the literal language of the claims, or if they include equivalent materials with insubstantial differences from the literal languages of the claims.

### REFERENCES

### US/EP?WO/CN Patent Documents

EP2637862 A1—Barbaros—September 2013
WO2013105768 A1—Lee—July 2013
WO2011016832 A2—Veerasamy—February 2011
U.S. Pat. No. 8,650,749 B2—Marinera, February 2014
CN203083964 U—Goin—July 2013
US0082984 A1—Drzaic—April 2013
US0027161 A1—Lee—January 2014
WO2013149446 A1—Wu—October 2013
US0329366 A1—Wang—December 2013
US0085713 A1—Balandin—April 2010
US0128439 A1—Tilak—May 2010
US0264041 A1—Zhamu—October 2013
U.S. Pat. No. 8,519,450 B1—Zhu—August 2013
U.S. Pat. No. 8,557,686 B1—Zhu—October 2013
U.S. Pat. No. 8,591,680 B2—Veerasamy—November 2013
CN103151101 A—Ping—December 2013
WO2013051761 A1—Lee—April 2013
EP2439779 A2—Yoon—April 2012
CN103279239 A—Haofei—May 2013
US0061612 A1—Yamazaki—March 2014
US0049463 A1—Seo—February 2014
US0055429 A1—Kwon—February 2014
US0043263—Park—February 2014
EP2327662 A1—Yoon—January 2011
US0049464 A1—Kwak—February 2014
US0055429 A1—Kwon—February 2014
US0034926 A1—Matsubara—February 2014
WO2014030954 A2—Kwon—February 2014
US0313512 A1—Yang—November 2013
US0048774 A1—Cohen—February 2014
US0000805 A1—Bowers—January 2014
US0030600 A1—Kwon—January 2014
US0065402 A1—Suckeveriene—March 2014
WO2014030957 A1—Kook—February 2014
WO2014035148 A1—Seo—March 2014
WO2014038898 A1—Kook—March 2014
WO2014021658 A1—Kook—February 2014
WO2014033282 A1—Van—March 2014
CN103413951 A—Week—November 2013
CN103490478 A—Shen—January 2014
CN103432994 A—Dong—December 2013
CN103413950 A—Chun —November 2013
WO2014028978 A1—Dan—February 2014
CN103428972 A—Wang—December 2013
WO2014020915 A1—Kaneda—February 2014
EP2439779 A2—Yoon—April 2011
US0053973 A1—Shin—February 2014
US0022533 A1—Fermann—January 2014
US0026155 A1—Valin—January 2014
US0011673 A1—Lefevre—January 2014
US0061060 A1—McAlister—March 2014
US0049879 A1—Snyder—February 2014
US0030181 A1—Liu—January 2014
WO2014030954—Kwon—February 2014
WO2014038898—Kook—March 2014
US0055429 A1—Kwon—February 2014
US0042390 A1—Gruner—February 2014
US0030600 A1—Kwon—January 2014
EP2706435 A2—Kook—March 2014
US0065402 A1—Suckeveriene—March 2014
US0086631 A1—Yu Kai Han—May 2014
US0237679 A1—Conor F. Madigan—September 2012

### Publications

[1] http://www.colorado.edu/news/releases/2011/08/23/unexpected-adhesion-properties-graphene-may-lead-new-nanotecnology-devices—Aug. 23, 2011, Engineering, Computational Science & Engineering, Discovery & Innovation, Graduate Education, Student Research
[2] http://www.nature.com/srep/2013/130916/srep02660/full/srep02660.html, Anomalous interface adhesion of graphene membranes, Y. He, W. F. Chen, W. B. Yu, G. Ouyang & G. W. Yang, Scientific Reports 3, Article number: 2660, September 2013
[3] Bilayer Graphene works as an insulator, UC Riverside, January 2012, UCR Newsroom
[4] http://www.information-age.com/technology/applications-and-development/123457677/scientists-build-most-sophisticated-graphene-circuit-date, January 2014, Information Age, Applications and development, Chloe Green
[5] http://ucrtoday.ucr.edu/17286, UCR Today: Advancing Graphene for Post-Silicon Computer logic, September 2013, www.ucr.edu, Sean Nealon
[6] Compatible graphene photodetector covering all optical communication bands, Andreas Pospischil, Markus Humer, Marco M. Furchi, Dominic Bachmann, Romain Guider, Thomas Fromherz, and Thomas Mueller, Austria, Nature, February 2013
[7] http://newscenter.berkeley.edu/2011/05/08/graphene-optical-modulators-ultrafast-communications/—UC Berkeley Newsletter, Sarah Yang, May 2011
[8] http://www.nature.com/nature/journal/v462/n7271/full/nature08569.html?message=remove&free=2, Nature 462, 339-341 (19 Nov. 2009)|doi:10.1038/nature08569; Received 20 Jul. 2007; Accepted 1 Oct. 2009, Ultraflat Graphene, Chun Hung Lui, Li Liu, Kin Fai Mak, George W. Flynn & Tony F. Heinz
[9] www.nature.com/doifinder/10.1038/nature08569, Ultraflat graphene, Nature letters, Chun Hung Lui, Li Liu, Kin Fai Mak, George W. Flynn & Tony F. Heinz
[10] Wireless power transmission to sensors using mobile carrier hosts, Navin Srivastava, Arush Saxena and Chetali Tyagi, Dept. of Electronics Engineering, Bharati Vidyapeeth Deemed University, Pune, India, Special Issue of International Journal of Sustainable Development and Green Economics (IJSDGE), ISSN No.: 2315-4721, V-2, I-1, 2, 2013
[11] The application of graphene as electrodes in electrical and optical devices, Gunho Jo, Minhyeok Choe, Sangchul Lee, Woojin Park, Yung Ho Kahng and Takhee Lee, IOP Science Nanotechnology, Gunho Jo et al 2012 Nanotechnology 23 112001
[12] Structural forms of single crystal semiconductor nanoribbons for high-performance stretchable electronics, Yugang Sun and John A. Rogers, www.rsc.org/materials, 2007, DOI: 10.1039/b614793c.
[13] Materials and Mechanics for Stretchable Electronics, John A. Rogers, Takao Someya and Yonggang Huang, Science Review, vol 327, March 2010, www.sciencemag.org.
[14] Nanoparticle-doped electrically-conducting polymers for flexible nano-micro systems, Ajit Khosla, The Electrochemical Society Interface, Fall-winter 2012.
[15] Polydimethylsiloxane-based self-healing materials, Soo Hyoun Cho, Magnus Andersson, Scott R. White, Nancy R. Sottos and Paul V. Braun, Advanced Materials, 2006, 16, 997-1000.
[16] Extremely efficient flexible organic light-emitting diodes with modified graphene anode, Tae-Hee Han, Youngbin Lee, Mi-Ri Choi, Seong-Hoon Woo, Sang-Hoon Bae, Byung Hee Hong, Jong-Hyun Ahn and Tae-Woo Lee, Nature Photonics, vol 6, February 2012, www.nature.com/naturephotonics.
[17] http://www.information-age.com/technology/applications-and-development/123457677/scientists-build-most-sophisticated-graphene-circuit-date
[18] http://spie.org/Publications/Proceedings/Paper/10.1117/12.2003936
[19] http://www.kurzweilai.net/atomically-thin-strong-graphene-based-integrated-circuits
[20] http://www.gizmag.com/graphene-ink-foldable-electronics/27622/

1. A foldable electronic display that can be unfolded and used as a monitor comprising a plurality of layers, each formed with an allotrope of carbon and clubbed together to form a composite display sheet.

2. The display of claim 1 in which the allotrope of carbon is material selected from graphene, carbon nano-tubes and carbon nano-fibers.

3. The display of claim 1 including nanobubbles to provide enhanced flexibility, bending capacity, cushioning and foldability.

4. The display of claim 1 including a material that provides shock-absorbance and stress or strain relief whereby to enable revival of the original shape of the display after unfolding.

5. The display of claim 1 in which there are seven of layers.

6. The display of claim 1 in which the top most layer transparent, conductive and optical-intensive whereby to provide a high optical resolution.

7. The display of claim 1 wherein a first layer is a composite of graphene mixed with polymers, chemicals, or elastomers, acting as a shield.

8. The display of claim 7 wherein a second layer attached to the first layer acts as a display screen.

9. The display of claim 8 wherein a third layer is printed with circuitry of the device.

10. The display of claim 9 in which a layer is provide that dissipates heat.

11. The display of claim 10 wherein a final layer has insulator properties.

12. A method of forming a foldable electronic display that can be unfolded and used as a monitor comprising providing a plurality of layers, each formed with an allotrope of carbon and clubbing the layers together to form the display sheet.

13. The method of claim 12 including forming a nonmetal layer over the entire upper surface of a carrier member and forming an electrode pattern thereon.

14. The method of claim 13 including forming a layer that has the capability of storing energy.

15. The method of claim 14 including providing a layer that dissipates heat.

16. The method of claim 15 including providing an insulator layer.
